(19) United States
(12) Patent Application Publication
(10) Pub. No.: US 2026/0182206 A1
(43) Pub. Date: Jun. 25, 2026

(54) DISPLAY DEVICE

(71) Applicant: LG Display Co., Ltd., Seoul (KR)

(72) Inventor: Yongju Kim, Goyang-si (KR)

(73) Assignee: LG Display Co., Ltd., Seoul (KR)

(21) Appl. No.: 19/403,771

(22) Filed: Nov. 28, 2025

(30) Foreign Application Priority Data
Dec. 19, 2024 (KR) 10-2024-0190899

(51) Int. Cl. H10K 59/80; H10K 102/00

(52) U.S. Cl. CPC H10K 59/871; H10K 2102/311

(57) ABSTRACT

Disclosed is a display device that prevents or suppresses damage to an inorganic layer or a data line layer during a bending process of a display panel. The display device includes a display panel including a display area, a non-display area, and a bendable area; first and second back plates supporting the display panel; and a curved cover member having a cavity having a predetermined depth defined therein, wherein the first and second back plates are seated in the cavity, wherein the curved cover member has a flange disposed outwardly of the cavity, wherein a general shape of the curved cover member is a sprue shape, wherein the display panel has a bent portion in the bendable area, and wherein the second back plate includes a flat portion corresponding to the display area, and a bending stress relief hole is formed in the flat portion.

### CROSS REFERENCE TO RELATED APPLICATION

Pursuant to 35 U.S.C. § 119 (a), this application claims the benefit of an earlier filing date and right of priority to Korean Patent Application No. 10-2024-0190899, filed on Dec. 19, 2024, in the Korean Intellectual Property Office, the contents of which are incorporated by reference herein in their entirety.

### BACKGROUND

### Field

The present disclosure relates to a display device having a curved cover member.

### Description of Related Art

Display devices are applied to various electronic devices, such as TV, mobile phones, laptops, tablets, watches, etc.

Display devices include, among others, an organic light-emitting display device (OLED) that emits light by itself, and a liquid crystal display device (LCD) that requires a separate light source.

Recently, a display device including a light-emitting diode (LED) has attracted attention as a next-generation display device. Since the light-emitting diode is made of an inorganic material rather than an organic material, the display device including the light-emitting diode may have a faster lighting speed than that of the liquid crystal display device or the organic light-emitting display device, and may have excellent luminous efficiency, and may display an image with high luminance.

### SUMMARY

An organic light-emitting display device has been developed as a curved display device in which each of both opposing edges of a flexible display device or four edges of upper, lower, left, and right sides thereof is bent. The curved display device refers to a display device in which a flexible display module having flexibility is attached to a curved cover member.

However, the curved display device has a problem in that an inorganic layer and a data line layer are periodically, repeatedly, and randomly damaged during the bending process of the display panel.

To solve the above-described problem, the inventor of the present disclosure has invented a display device that prevents or suppresses damage to an inorganic layer or a data line layer during a bending process of a display panel.

A purpose according to an aspect of the present disclosure is to provide a display device capable of preventing or suppressing damage by forming a bending stress relief hole in a support member supporting a display panel to relieve bending stress generated during a bending process of the display panel.

Purposes according to the present disclosure are not limited to the above-mentioned purpose. Other purposes and advantages according to the present disclosure that are not mentioned may be understood based on following descriptions, and may be more clearly understood based on embodiments according to the present disclosure. Further, it will be easily understood that the purposes and advantages according to the present disclosure may also be realized by practicing the examples described herein, including in the claims or combinations thereof.

A display device according to an example embodiment of the present disclosure includes a display panel including a display area, a non-display area, and a bendable area; a first back plate and a second back plate supporting the display panel; and a curved cover member having a cavity having a predetermined depth defined therein, wherein the first back plate and the second back plate are seated in the cavity, wherein the curved cover member has a flange having a predetermined height and disposed outwardly of the cavity, wherein a general shape of the curved cover member is a sprue shape, wherein the display panel has a bent portion in the bendable area, and wherein the second back plate includes a flat portion corresponding to the display area, and a bending stress relief hole is formed in the flat portion.

According to an example embodiment of the present disclosure, the bending stress is relieved due to the bending stress relief hole formed in the second back plate bent together with the display panel during the bending process of the display panel, thereby preventing or suppressing damage to the panel.

In addition, according to an example embodiment of the present disclosure, the bending stress is not transmitted to the inorganic layer or the data line layer in the bending process of the display panel, thereby preventing or suppressing manufacturing defects of the display panel.

In addition, according to an example embodiment of the present disclosure, the occurrence of defects in the display panel during the manufacturing process may be prevented or suppressed, thereby reducing the defect rate of the display device.

In addition, according to an example embodiment of the disclosure, a decrease in the lifespan of the display device may be prevented or suppressed by reducing the defect rate of the display device.

In addition, according to an example embodiment of the present disclosure, as the defect rate of the display device is reduced, there is an effect of reducing power consumption.

In addition, according to an example embodiment of the present disclosure, as the defect rate of the display device is reduced, there is an effect that a long-life low-power display device may be provided.

In addition, in the display device according to example embodiments of the present disclosure, as the panel defects are prevented or suppressed in the process of manufacturing the display device, the reduction of the lifespan of the panel may be prevented or suppressed, and improvement of the quality of the display device may be realized.

In addition, in the display device according to example embodiments of the present disclosure, stably manufacturing the display panel in a manufacturing process may result in improving product quality and securing product reliability.

The effects of the present disclosure are not limited to the above-mentioned effects, and other effects not mentioned may be clearly understood by those skilled in the art from the following descriptions.

In addition to the above-described effects, the specific effects of the present disclosure will be described together while describing specific matters for implementing the example embodiments of the present disclosure below.

### BRIEF DESCRIPTION OF THE DRAWINGS

The accompanying drawings, which are included to provide a further understanding of the present disclosure and are incorporated in and constitute a part of this application, illustrate example embodiments of the present disclosure and together with the description serve to explain the principles of the disclosure. In the drawings:

FIG. 1 is a perspective view illustrating a display device according to an example embodiment.

FIG. 2 is a plan view of a display device according to an example embodiment of the present disclosure.

FIG. 3 is a cross-sectional view of a display device according to an example embodiment of the present disclosure.

FIG. 4 is a diagram illustrating a state of a support member unfolded before bending of a display panel according to an example embodiment of the present disclosure.

FIG. 5 is a diagram illustrating an example in which a bending stress relief hole is formed in a second back plate according to an example embodiment of the disclosure.

FIG. 6 is a diagram illustrating a bending process of a display panel and a second back plate according to an example embodiment of the present disclosure.

FIG. 7 is a diagram illustrating an example in which a flange edge of a cover member is vertically aligned with a bending stress relief hole before bending of a second back plate according to an example embodiment of the disclosure.

FIG. 8 is a diagram illustrating a state after the second back plate is bent according to an example embodiment of the present disclosure.

FIG. 9 is a perspective view illustrating a state in which the second back plate is seated in a cavity defined in a curved cover member after the display panel is bent according to an example embodiment of the disclosure.

FIG. 10 is a cross-sectional view illustrating a state in which the second back plate is seated in a cavity defined in a curved cover member after the display panel is bent according to an example embodiment of the disclosure.

### DETAILED DESCRIPTION

Advantages and features of the present disclosure, and a method of achieving the advantages and features will become apparent with reference to example embodiments described below in detail together with the accompanying drawings. However, the present disclosure is not limited to the example embodiments as disclosed below but may be implemented in various different forms. Thus, these embodiments are set forth only to make the present disclosure more complete and to more fully inform the scope of the present disclosure to those of ordinary skill in the technical field to which the present disclosure belongs. The protected scope of the present disclosure may be defined by the scope of the claims and their equivalents.

For simplicity and clarity of illustration, elements in the drawings are not necessarily drawn to scale. The same reference numbers in different drawings represent the same or similar elements, and as such perform similar functionality. Further, descriptions and details of well-known steps and elements may be omitted for simplicity of the description. Furthermore, in the following detailed description of the present disclosure, numerous specific details are set forth to provide a thorough understanding of the present disclosure. However, it should be understood that the present disclosure may be practiced without these specific details. In other instances, well-known methods, procedures, components, and circuits have not been described in detail so as not to unnecessarily obscure aspects of the present disclosure.

Examples of various embodiments are illustrated and described further below. It should be understood that the description herein is not intended to limit the claims to the specific embodiments described. On the contrary, it is intended to cover alternatives, modifications, and equivalents as may be included within the spirit and scope of the present disclosure as defined by the appended claims and their equivalents.

A shape, a size, a ratio, an angle, a number, etc., disclosed in the drawings for illustrating embodiments of the present disclosure are illustrative, and the present disclosure is not limited thereto. The terminology used herein is directed to the purpose of describing particular embodiments only and is not intended to be limiting of the present disclosure. As used herein, the singular constitutes “a” and “an” are intended to include the plural constitutes as well, unless the context clearly indicates otherwise. It should be further understood that the terms “comprise”, “comprising”, “include”, and “including” when used in this specification, specify the presence of the stated features, integers, operations, elements, and/or components, but do not preclude the presence or addition of one or more other features, integers, operations, elements, components, and/or portions thereof. As used herein, the term “and/or” includes any and all combinations of one or more of associated listed items.

Expression such as “at least one of” when preceding a list of elements may modify the entire list of elements and may not modify the individual elements of the list. In interpretation of numerical values, an error or tolerance therein may occur even when there is no explicit description thereof.

In addition, it should also be understood that when a first element or layer is referred to as being present “on” a second element or layer, the first element may be disposed directly on the second element or may be disposed indirectly on the second element with a third element or layer being disposed between the first and second elements or layers. It should be understood that when a first element or layer is referred to as being “connected to”, or “coupled to” a second element or layer, the first element may be directly connected to or coupled to the second element or layer, or one or more intervening elements or layers may be present therebetween. In addition, it should also be understood that when an element or layer is referred to as being “between” two elements or layers, it may be the only element or layer between the two elements or layers, or one or more intervening elements or layers may also be present therebetween. Further, as used herein, when a layer, film, area, plate, or the like is disposed “on” or “on a top” of another layer, film, area, plate, or the like, the former may directly contact the latter or still another layer, film, area, plate, or the like may be disposed between the former and the latter. As used herein, when a layer, film, area, plate, or the like is directly disposed “on” or “on a top” of another layer, film, area, plate, or the like, the former directly contacts the latter and still another layer, film, area, plate, or the like is not disposed between the former and the latter. Further, as used herein, when a layer, film, area, plate, or the like is disposed “below” or “under” another layer, film, area, plate, or the like, the former may directly contact the latter or still another layer, film, area, plate, or the like may be disposed between the former and the latter. As used herein, when a layer, film, area, plate, or the like is directly disposed “below” or “under” another layer, film, area, plate, or the like, the former directly contacts the latter and still another layer, film, area, plate, or the like is not disposed between the former and the latter.

In descriptions of temporal relationships, for example, temporal precedent relationships between two events such as “after”, “subsequent to”, “before”, etc., another event may occur therebetween unless “directly after”, “directly subsequent” or “directly before” is not indicated. When a certain embodiment may be implemented differently, a function or an operation specified in a specific block may occur in a different order from an order specified in a flowchart. For example, two blocks in succession may be actually performed substantially concurrently, or the two blocks may be performed in a reverse order depending on a function or operation involved.

It should be understood that, although the terms “first”, “second”, “third”, and so on may be used herein to describe various elements, components, areas, layers and/or periods, these elements, components, areas, layers and/or periods should not be limited by these terms. These terms are used to refer to one element, component, area, layer or section separately from another element, component, area, layer or section. Thus, a first element, component, area, layer or section as described under could be termed a second element, component, area, layer or section, and vice versa, without departing from the spirit and scope of the present disclosure.

Where an embodiment may be implemented differently, functions or operations specified within a specific block may be performed in a different order from an order specified in a flowchart. For example, two consecutive blocks may actually be performed substantially simultaneously, or the blocks may be performed in a reverse order depending on related functions or operations. The features of the various embodiments of the present disclosure may be partially or entirely combined with each other, and may be technically associated with each other or operate with each other. The embodiments may be implemented independently of each other and may be implemented together in an association relationship.

In interpreting a numerical value, the value is interpreted as including an error range unless there is no separate explicit description thereof. Unless otherwise defined, all terms including technical and scientific terms used herein have the same meaning as commonly understood by one of ordinary skill in the art to which this inventive concept belongs. It should be further understood that terms, such as those defined in commonly used dictionaries, should be interpreted as having a meaning that is consistent with their meaning in the context of the relevant art and will not be interpreted in an idealized or overly formal sense unless expressly so defined herein.

As used herein, “embodiments,” “examples,” “aspects,” etc., should not be construed such that any aspect or design as described is superior to or advantageous over other aspects or designs. Further, the term ‘or’ means ‘inclusive or’ rather than ‘exclusive or’. That is, unless otherwise stated or clear from the context, the expression that ‘x uses a or b’ means one of natural inclusive permutations.

The terms used in the description as set forth below have been selected as being general and universal in the related technical field. However, there may be other terms than the terms depending on the development and/or change of technology, convention, preference of technicians, etc. Therefore, the terms used in the description as set forth below should not be understood as limiting technical ideas, but should be understood as examples of the terms for illustrating embodiments. Further, in a specific case, a term may be arbitrarily selected by the applicant, and in this case, the detailed meaning thereof will be described in a corresponding description period. Therefore, the terms used in the description as set forth below should be understood based on not simply the name of the terms, but the meaning of the terms and the contents throughout the Detailed Descriptions.

In description of flow of a signal, for example, when a signal is delivered from a node A to a node B, this may include a case where the signal is transferred from the node A to the node B via another node unless a more limiting phrase like ‘immediately transferred’ or ‘directly transferred’ is used. Throughout the present disclosure, “A and/or B” means A, B, or A and B, unless otherwise specified, and “C to D” means C inclusive to D inclusive unless otherwise specified.

As used herein, a first direction, a second direction, and a third direction, or an X-axis direction, a Y-axis direction, and a Z-axis direction should not be interpreted only as having a geometric relationship with each other in which the first direction, the second direction, and the third direction are perpendicular to each other or the X-axis direction, the Y-axis direction, and the Z-axis direction are perpendicular to each other, but may be interpreted as having a geometric relationship with each other in which the first direction, the second direction, and the third direction interest each other at an angle other than 90 degrees or the X-axis direction, the Y-axis direction, and the Z-axis direction are interest each other at an angle other than 90 degrees within a range in which a configuration of the present disclosure may work functionally.

Where a first component or layer is described as “contacting” or “overlapping” a second component or layer, it should be understood that the first component or layer may directly contact or overlap the second component or layer, or a third component or layer may be interposed between the first and second components or layers that may indirectly contact or overlap each other unless otherwise specified.

Hereinafter, various example embodiments of the present disclosure will be described in detail with reference to the accompanying drawings.

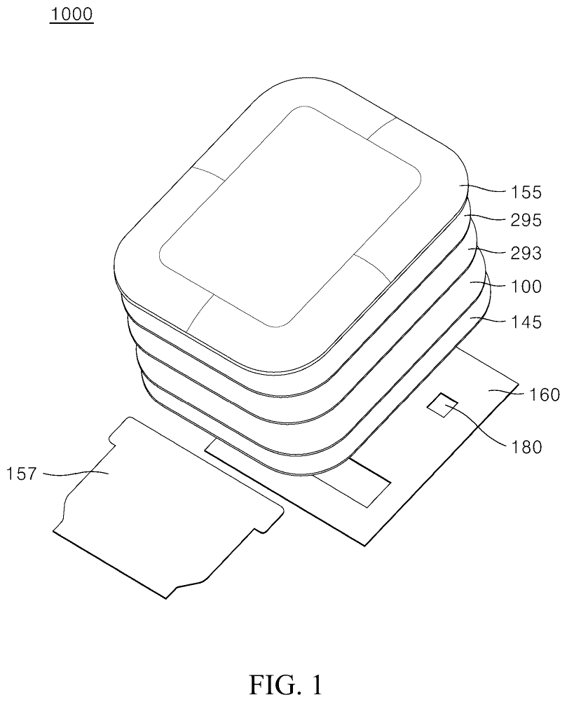

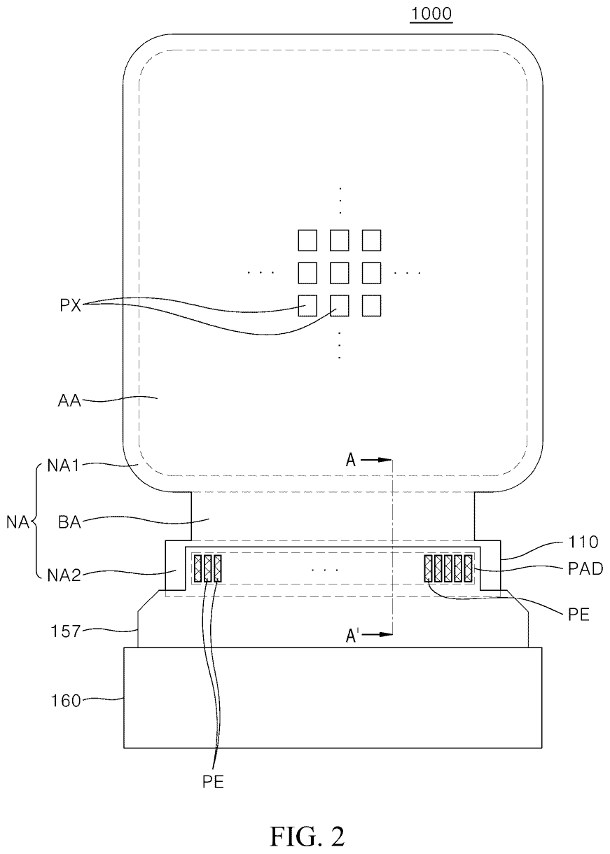

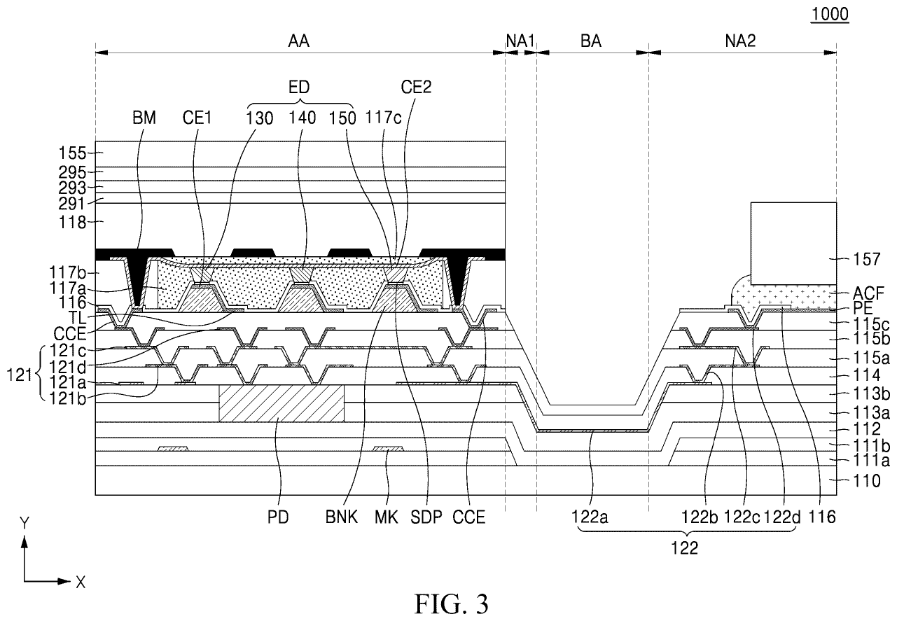

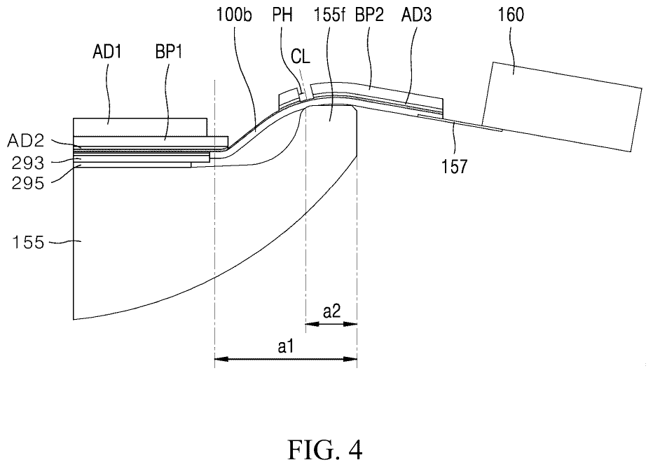

FIG. 1 is an exploded perspective view of a display device according to an example embodiment of the present disclosure. FIG. 2 is a plan view of a display device according to an example embodiment of the present disclosure. FIG. 3 is a cross-sectional view of a display device according to an example embodiment of the present disclosure. For example, FIG. 3 is a cross-sectional view of a display area AA, a first non-display area NA1, a bendable area BA, and a second non-display area NA2. FIG. 4 is a diagram illustrating a state of a support member unfolded before bending of a display panel according to an embodiment of the present disclosure.

As shown in FIGS. 1 to 3, a display device 1000 according to an embodiment of the present disclosure may include a display panel 100, a polarizing layer 293, an adhesive layer 295, a curved cover member 155, a support member 145, a flexible circuit board 157, and a printed circuit board 160.

For example, the display device 1000 may include a substrate 110. The substrate 110 may be a member supporting other components of the display device 1000. The substrate 110 may be made of an insulating material. For example, the substrate 110 may be made of glass or resin. In addition, the substrate 110 may be made of a material having flexibility. For example, the substrate 110 may be made of a plastic material having flexibility, such as polyimide (PI). However, embodiments of the present disclosure are not limited thereto.

The display panel 100 may implement information, a video, and/or an image to be provided to a user. For example, the display panel 100 may include a display area AA, a non-display area NA and a bendable area BA. For example, the substrate 110 may include the display area AA and the non-display area NA. The distinction between the display area AA and the non-display area NA is applied not only to the substrate 110 but also to the display device 1000.

The display area AA may be an area in which an image is displayed. The display area AA may include a plurality of pixels PX. Each of the plurality of pixels PX may be composed of a plurality of sub-pixels. A plurality of light-emitting elements may be disposed in each of the plurality of sub-pixels SP. A type of each of the plurality of light-emitting elements may vary according to a type of the display device 1000. For example, when the display device 1000 is an inorganic light-emitting display device, the light-emitting element may be a light-emitting diode (LED), a micro light-emitting diode (LED), or a mini light-emitting diode (LED). However, embodiments of the present disclosure are not limited thereto.

The non-display area NA may be an area in which no image is displayed. Various lines and circuits for driving the plurality of pixels PX of the display area AA may be disposed in the non-display area NAA. For example, various wires and driving circuits may be mounted in the non-display area NA, and a pad PAD to which an integrated circuit, a printed circuit, etc. are connected may be disposed in the non-display area NA. However, embodiments of the present disclosure are not limited thereto.

For example, the driving circuit may be a data driving circuit and/or a gate driving circuit. However, embodiments of the present disclosure are not limited thereto. Wires to which a control signal for controlling the driving circuits is supplied may be disposed. For example, the control signal may include various timing signals including a clock signal, an input data enable signal, and synchronization signals. However, embodiments of the present disclosure are not limited thereto. The control signal may be received via the pad PAD. For example, link lines for transmitting signals may be disposed in the non-display area NA. For example, driving components such as a flexible printed circuit board 157 and a printed circuit board 160 may be connected to the pad PAD.

According to the present disclosure, the non-display area NA may include a first non-display area NA1, a bendable area BA, and a second non-display area NA2. For example, the first non-display area NA1 may be an area surrounding at least a portion of the display area AA. The bendable area BA is an area extending from at least one of a plurality of sides of the first non-display area NA1 and may be a bendable area. The second non-display area NA2 may be an area extending from the bendable area BA, and the pad PAD may be disposed in the second non-display area. For example, the bendable area BA may be in a bent state, and the remaining area of the substrate 110 except for the bendable area BA may be in a flat state. In this case, as the bendable area BA is bent, the second non-display area NA2 may be located on a rear surface of the display area AA. However, embodiments of the present disclosure are not limited thereto.

The display area AA of the substrate 110 or the display device 1000 may be formed in various shapes according to the designs of the display device 1000. For example, the display area AA may be formed in a rectangular shape having four corners of a round shape. However, embodiments of the present disclosure are not limited thereto. In another example, the display area AA may be formed in a rectangular shape in which four corners have a right angle or a circular shape. However, embodiments of the present disclosure are not limited thereto.

According to the present disclosure, a width of the second non-display area NA2 in which a plurality of pad electrodes PE are disposed may be greater than a width of the bendable area BA in which only a plurality of link lines are disposed. In addition, the width of the display area AA in which the plurality of sub-pixels are disposed may be greater than the width of the bendable area BA in which only the plurality of link lines are disposed. Although the width of the bendable area BA is illustrated as being smaller than the width of the remaining area of the substrate 110 in the drawing, a shape of the substrate 110 including the bendable area BA is merely an example, and embodiments of the present disclosure are not limited thereto.

Although not shown in the drawings, a plurality of pixel driving circuits may be disposed in the display area AA. The plurality of pixel driving circuits may be circuits for driving the light-emitting elements of the plurality of sub-pixels. Each of the plurality of pixel driving circuits may include a plurality of transistors including a driving transistor, a storage capacitor, etc., and may control an emission operation of the plurality of light-emitting elements by supplying a control signal, a power, and a driving current to the light-emitting elements of the plurality of sub-pixels. For example, the pixel driving circuit may include a power line and a signal line for controlling the emission on/off and/or emission time of the light-emitting element. For example, each of the plurality of pixel driving circuits may be a driver manufactured using a metal-oxide-silicon field effect transistor (MOSFET) manufacturing process and disposed on a semiconductor substrate. However, embodiments of the present disclosure are not limited thereto. A driver may include the plurality of pixel driving circuits and may drive the plurality of sub-pixels. For example, the plurality of pixel driving circuits may include a micro driver (uDriver). However, embodiments of the present disclosure are not limited thereto. For example, each of the plurality of pixel driving circuits may include a driving chip. However, embodiments of the present disclosure are not limited thereto.

As shown in FIG. 1, the flexible circuit board 157 and the printed circuit board 160 may be disposed under the display panel 100. The flexible circuit board 157 and the printed circuit board 160 may be disposed at least at one edge of the display panel 100. However, embodiments of the present disclosure are not limited thereto. One side of the flexible circuit board 157 may be attached to the display panel 100 and the other side thereof may be attached to the printed circuit board 160. However, embodiments of the present disclosure are not limited thereto. The flexible circuit board 157 may be a flexible film. However, embodiments of the present disclosure are not limited thereto.

The pad PAD including a plurality of pad electrodes PE may be disposed in the second non-display area NA2. A driving component including one or more flexible circuit boards (or flexible films) 157 and the printed circuit board 160 may be attached or bonded to the pad PAD. The plurality of pad electrodes PE of the pad PAD may be electrically connected to one or more flexible circuit boards (or flexible films) 157, and may transmit various signals (or power) from the printed circuit board 160 and the flexible circuit boards (or flexible films) 157 to the plurality of pixel driving circuits of the display area AA.

The flexible circuit board (or flexible film) 157 may be a film in which various components are disposed on a flexible base film. For example, a driving IC such as a gate driver IC or a data driver IC may be disposed on the flexible circuit board (or flexible film) 157. However, embodiments of the present disclosure are not limited thereto. The driving IC DT may be a component that processes data for displaying an image and a driving signal. The driving IC DT may be disposed in a manner such as a Chip On Glass (COG), a Chip On Film (COF), or a Tape Carrier Package (TCP) according to a mounted manner. However, embodiments of the present disclosure are not limited thereto. The flexible circuit board (or flexible film) 157 may be attached or bonded to the plurality of pad electrodes PE via a conductive adhesive layer. However, embodiments of the present disclosure are not limited thereto.

The printed circuit board 160 may be electrically connected to one or more flexible circuit boards (or flexible films) 157 and may be a component that supplies a signal to the driving IC. The printed circuit board 160 may be disposed on one side of the flexible circuit board (or flexible film) 157 so as to be electrically connected to the flexible circuit board (or flexible film) 157. Various components for supplying various signals to the driving IC may be disposed on the printed circuit board 160. For example, various components such as a timing controller, a power supply unit, a memory, or a processor may be disposed on the printed circuit board 160. For example, the printed circuit board 160 may include a power management integrated circuit (PMIC). However, embodiments of the present disclosure are not limited thereto.

The printed circuit board 160 may include at least one hole 180. However, embodiments of the present disclosure are not limited thereto. An internal component for sensing ambient light or temperature that may be provided to the plurality of sensors may be disposed in an area corresponding to the at least one hole 180. For example, the internal component may include an ALS (Ambient light sensor), a temperature sensor, etc. However, embodiments of the present disclosure are not limited thereto. For example, the hole 180 may be a transmission hole or the like. However, embodiments of the present disclosure are not limited thereto.

As shown in FIG. 1, the polarizing layer 293 may be disposed on the display panel 100. The polarizing layer 293 may prevent or reduce light generated from an external light source from entering the display panel 100 and thus affecting the light-emitting element or the like.

The support member 145 may be disposed between the display panel 100 and the printed circuit board 160. The support member 145 may support the display panel 100 and may reinforce the rigidity of the display panel 100. The support member 145 may be a back plate. However, embodiments of the present disclosure are not limited thereto. For example, the support member 145 may include a first back plate BP1 and a second back plate BP2.

The curved cover member 155 has a flange 155f as an outer edge thereof which has a predetermined vertical level. The first back plate BP1 and the second back plate BP2 are seated on the flange 155f. A cavity having a predetermined depth is defined in the curved cover member 155 and is disposed inwardly of the flange 155f, so that an entirety of the curved cover member 155 may have a sprue shape.

The curved cover member 155 may be disposed on the polarizing layer 293. The curved cover member 155 may be a member for protecting the display panel 100. The adhesive layer 295 may be disposed between the polarizing layer 293 and the curved cover member 155. The curved cover member 155 may be attached to the display panel 100 via the adhesive layer 295. The adhesive layer 295 may include an OCA (Optically clear adhesive), an OCR (Optically clear resin), a PSA (Pressure sensitive adhesive), etc. However, embodiments of the present disclosure are not limited thereto.

Although not shown in the drawing, the plurality of link lines may be disposed in the non-display area NA. The plurality of link lines may be lines for transmitting various signals from one or more flexible circuit boards (or flexible films) 157 and the printed circuit board 160 to the display area AA. The plurality of link lines may extend from the plurality of pad electrodes PE of the second non-display area NA2 toward the bendable area BA and the first non-display area NA1 and may be electrically connected to the plurality of driving lines of the display area AA. The plurality of pixel driving circuits may be driven upon receiving signals from one or more flexible circuit boards (or flexible films) 157 and the printed circuit boards 160 via driving lines of the display area AA and the link lines of the non-display area NA.

For example, a plurality of driving lines together with the plurality of link lines may transmit signals output from the flexible circuit board (or flexible film) 157 and the printed circuit board 160 to the plurality of pixel driving circuits. The plurality of driving lines may be disposed in the display area AA and may be electrically connected to each of the plurality of pixel driving circuits. The plurality of driving lines may extend from the display area AA toward the non-display area NA and may be electrically connected to the plurality of link lines. Accordingly, the signals output from the flexible circuit board (or flexible film) 157 and the printed circuit board 160 may be transmitted to each of the plurality of pixel driving circuits via the plurality of link lines and the plurality of driving lines.

As the bendable area BA is bent, a portion of each of the plurality of link lines may also be bent. Thus, stress is concentrated on a portion of the bent link line, and accordingly, a crack may occur in the link line. Accordingly, the plurality of link lines may be made of a conductive material having excellent ductility to reduce the cracks occurring when the bendable area BA is bent. For example, the plurality of link lines may be made of a conductive material having excellent ductility, such as gold (Au), silver (Ag), aluminum (Al), etc. However, embodiments of the present disclosure are not limited thereto. In addition, the plurality of link lines may be made of one of various conductive materials used in the display area AA. For example, the plurality of link lines may be made of molybdenum (Mo), chromium (Cr), titanium (Ti), nickel (Ni), neodymium (Nd), copper (Cu), an alloy thereof, or an alloy of silver (Ag) and magnesium (Mg). However, embodiments of the present disclosure are not limited thereto. The plurality of link lines may be configured in a multilayer structure including various conductive materials. For example, the plurality of link lines may be configured in a triple layer structure of a titanium (Ti) layer/aluminum (Al) layer/titanium (Ti) layer. However, embodiments of the present disclosure are not limited thereto.

The plurality of link lines may be formed in various shapes to reduce the stress. At least a portion of each of the plurality of link lines disposed on the bendable area BA may extend in the same direction as an extending direction of the bendable area BA, or may extend in a direction different from the extending direction of the bendable area BA to reduce the stress. For example, when the bendable area BA extends in one direction from the first non-display area NA1 toward the second non-display area NA2, at least a portion of the link line disposed on the bendable area BA may extend in a direction inclined with respect to the one direction. In another example, at least a portion of each of the plurality of link lines may be formed in each of patterns of various shapes. For example, at least a portion of each of the plurality of link lines disposed on the bendable area BA may have a shape in which conductive patterns having at least one of a diamond shape, a rhombus shape, a trapezoidal shape, a triangular wave shape, a sawtooth wave shape, a sine wave shape, a circular shape, and an omega ((2) shape are repeatedly arranged. However, embodiments of the present disclosure are not limited thereto. Therefore, to minimize or reduce the stress concentrated on the plurality of link lines and the resulting crack, the shape of each of the plurality of link lines may be formed in various shapes including the above-described shape. However, embodiments of the present disclosure are not limited thereto.

As shown in FIG. 3, a first buffer layer 111a and a second buffer layer 111b may be disposed one a remaining area of the substrate 110 except for the bendable area BA thereof.

Each of the first buffer layer 111a and the second buffer layer 111b may be disposed in the display area AA, the first non-display area NA1, and the second non-display area NA2. The first buffer layer 111a and the second buffer layer 111b may reduce penetration of moisture or impurities through the substrate 110. Each of the first buffer layer 111a and the second buffer layer 111b may be made of an inorganic insulating material. For example, each of the first buffer layer 111a and the second buffer layer 111b may be formed as a single layer or a multilayer made of silicon oxide (SiOx) or silicon nitride (SiNx). However, embodiments of the present disclosure are not limited thereto.

For example, a portion of each of the first buffer layer 111a and the second buffer layer 111b on the bendable area BA may be removed. The upper surface of the substrate 110 located in the bendable area BA may not be covered with the first buffer layer 111a and the second buffer layer 111b so as to be exposed. Removing the portion of each of the first buffer layer 111a and the second buffer layer 111b made of an inorganic insulating material from the bendable area BA may result in minimizing or suppressing cracks in the first buffer layer 111a and the second buffer layer 111b that may occur during the bending.

A plurality of alignment keys MK may be disposed between the first buffer layer 111a and the second buffer layer 111b. The plurality of alignment keys MK may be constructed to identify the position of the pixel driving circuit PD during the manufacturing process of the display device 1000. For example, the plurality of alignment keys MK may be constructed to align the position of the pixel driving circuit PD transferred onto an adhesive layer 112. In another example, the plurality of alignment keys MK may be omitted.

The adhesive layer 112 may be disposed on the second buffer layer 111b. The adhesive layer 112 may be disposed in the display area AA, the first non-display area NA1, the bendable area BA, and the second non-display area NA2. In another example, at least a portion of the adhesive layer 112 may be removed in the non-display area NA including the bendable area BA. For example, the adhesive layer 112 may be made of any one of an adhesive polymer, an epoxy resin, a UV curable resin, a polyimide-based resin, an acrylate-based resin, a urethane-based resin, and polydimethylsiloxane (PDMS). However, embodiments of the present disclosure are not limited thereto.

The pixel driving circuit PD may be disposed on the adhesive layer 112 in the display area AA. When the pixel driving circuit PD is embodied as a driving driver, the driving driver may be mounted on the adhesive layer 112 in a transfer process. However, embodiments of the present disclosure are not limited thereto.

A first protective layer 113a and a second protective layer 113b may be disposed on the adhesive layer 112 and the pixel driving circuit PD. The first protective layer 113a and the second protective layer 113b may be disposed to surround a side surface of the pixel driving circuit PD. However, embodiments of the present disclosure are not limited thereto. For example, the second protective layer 113b may be disposed to cover at least a portion of an upper surface of the pixel driving circuit PD. For example, at least one of the first protective layer 113a and the second protective layer 113b disposed on the bending area BA may be omitted. For example, the first protective layer 113a may be entirely disposed in the display area AA and the non-display area NA, and the second protective layer 113b may be partially disposed in the display area AA, the first non-display area NA1, and the second non-display area NA2. For example, a portion of the second protective layer 113b in the bending area BA may be removed. However, embodiments of the present disclosure are not limited thereto.

Each of the first protective layer 113a and the second protective layer 113b may be made of an organic insulating material. However, embodiments of the present disclosure are not limited thereto. For example, each of the first protective layer 113a and the second protective layer 113b may be made of a photoresist, polyimide (PI), or a photo acryl-based material. However, embodiments of the present disclosure are not limited thereto. For example, each of the first protective layer 113a and the second protective layer 113b may be embodied as an overcoat layer or an insulating layer. However, embodiments of the present disclosure are not limited thereto.

According to the present disclosure, a plurality of first connection lines 121 may be disposed on the second protective layer 113b and in the display area AA. The plurality of first connection lines 121 may be lines for electrically connecting the pixel driving circuit PD to other components. For example, the pixel driving circuit PD may be electrically connected to the plurality of signal lines TL and the plurality of contact electrodes CCE via the plurality of first connection lines 121. For example, the plurality of first connection lines 121 may include a (1-1)-th connection line 121a, a (1-2)-th connection line 121b, a (1-3)-th connection line 121c, and a (1-4)-th connection line 121d. However, embodiments of the present disclosure are not limited thereto.

For example, a plurality of (1-1)-th connection lines 121a may be disposed on the second protective layer 113b. The plurality of (1-1)-th connection lines 121a may be electrically connected to the pixel driving circuit PD. The plurality of (1-1)-th connection lines 121a may transmit a voltage output from the pixel driving circuit PD to the first electrode CE1 or the second electrode CE2.

For example, a third protective layer 114 may be disposed on the second protective layer 113b. The third protective layer 114 may be entirely disposed in the display area AA and the non-display area NA. In the bending area BA, the third protective layer 114 may cover a side surface of the second protective layer 113b and an upper surface of the first protective layer 113a. The third protective layer 114 may be made of an organic insulating material. For example, the third protective layer 114 may be made of a photoresist, polyimide (PI), or a photo acryl-based material. However, embodiments of the present disclosure are not limited thereto. For example, the first protective layer 113a, the second protective layer 113b, and the third protective layer 114 may be made of the same material. Embodiments of the present disclosure are not limited thereto.

A plurality of (1-2)-th connection lines 121b may be disposed on the third protective layer 114. The plurality of (1-2)-th connection lines 121b may be indirectly connected to the pixel driving circuit PD or may be directly connected thereto. For example, some of the (1-2)-th connection lines 121b may be directly connected to the pixel driving circuit PD via a contact hole of the third protective layer 114. The others of the (1-2)-th connection lines 121b may be electrically connected to the (1-1)-th connection line 121a via a contact hole of the third protective layer 114. However, embodiments of the present disclosure are not limited thereto. The voltage output from the pixel driving circuit PD may be transmitted to the first electrode CE1 or the second electrode CE2 via a connection line different from the plurality of (1-2)-th connection lines 121b.

A first insulating layer 115a may be disposed on the plurality of (1-2)-th connection lines 121a. The first insulating layer 115a may be entirely disposed in the display area AA and the non-display area NA. However, embodiments of the present disclosure are not limited thereto. The first insulating layer 115a may be made of an organic insulating material. However, embodiments of the present disclosure are not limited thereto. For example, the first insulating layer 115a may be made of a photo resist, polyimide (PI), or a photo acryl-based material. However, embodiments of the present disclosure are not limited thereto.

A plurality of (1-3)-th connection lines 121c may be disposed on the first insulating layer 115a. The plurality of (1-3)-th connection lines 121c may be electrically connected to the plurality of (1-2)-th connection lines 121b, respectively. For example, the (1-3)-th connection lines 121c may be electrically connected to the (1-2)-th connection line 121a via a contact hole of the first insulating layer 115a.

A second insulating layer 115b may be disposed on the plurality of (1-3)-th connection lines 121b. The second insulating layer 115b may be disposed in the remaining area except for the bending area BA. However, embodiments of the present disclosure are not limited thereto. The second insulating layer 115b may be disposed in the display area AA, the first non-display area NA1, and the second non-display area NA2. However, embodiments of the present disclosure are not limited thereto. For example, a portion of the second insulating layer 115b disposed in the bending area BA may be removed. The second insulating layer 115b may be made of an organic insulating material. However, embodiments of the present disclosure are not limited thereto. For example, the second insulating layer 115b may be made of a photo resist, polyimide (PI), or a photo acryl-based material. However, embodiments of the present disclosure are not limited thereto.

A plurality of (1-4)-th connection lines 121d may be disposed on the second insulating layer 115b. The plurality of (1-4)-th connection lines 121d may be electrically connected to the plurality of (1-3)-th connection lines 121c, respectively. For example, the (1-4)-th connection line 121d may be electrically connected to the (1-3)-th connection line 121b via a contact hole of the second insulating layer 115b.

According to the present disclosure, a plurality of second connection lines 122 may be disposed on the second protective layer 113b and in the non-display area NA. The plurality of second connection lines 122 may be lines for transmitting signals transmitted from the flexible circuit board 157 and the printed circuit board 160 (see FIG. 1) to the pad PAD to the pixel driving circuit PD of the display area AA. For example, the plurality of second connection lines 122 may be electrically connected to the plurality of pad electrodes PE respectively to receive signals from the flexible circuit board (or flexible film) 157 and the printed circuit board.

For example, the plurality of second connection lines 122 may extend from the pad PAD toward the display area AA to transmit signals to the lines of the display area AA. In this case, the plurality of second connection lines 122 may function as link lines LL. The plurality of second connection lines 122 may include a (2-1)-th connection line 122a, a (2-2)-th connection line 122b, a (2-3)-th connection line 122c, and a (2-4)-th connection line 122d.

A plurality of (2-1)-th connection lines 122a may be disposed on the second protective layer 113b. The plurality of (2-1)-th connection lines 122a may extend from the second non-display area NA2 to the bending area BA and the first non-display area NA1. The plurality of (2-1)-th connection lines 122a may transmit signals transmitted from the flexible circuit board (or flexible film) 157 and the printed circuit board to the pad PAD to the pixel driving circuit PD of the display area AA. For example, the (2-1)-th connection line 122a may be electrically connected to the pixel driving circuit PD via the first connection line 121 of the display area AA. The (2-1)-th connection line 122a may be electrically connected to the second electrode CE2 via the first connection line 121 and the contact electrode CCE of the display area AA.

A plurality of (2-2)-th connection lines 122b may be disposed on the third protective layer 114. The plurality of (2-2)-th connection lines 122b may be disposed in the second non-display area NA2. The (2-2)-th connection line 122b may be electrically connected to the (2-1)-th connection line 122a via a contact hole of the third protective layer 114. Accordingly, signals from the flexible circuit board (or flexible film) 157 and the printed circuit board may be transmitted to the (2-1)-th connection line 122b via the (2-1)-th connection line 122a.

The (2-3)-th connection line 122c may be disposed on the first insulating layer 115a. The (2-3)-th connection line 122c may be disposed in the second non-display area NA2. The (2-3)-th connection line 122c may be electrically connected to the (2-2)-th connection line 122a via a contact hole of the first insulating layer 115a. Accordingly, signals from the flexible circuit board (or flexible film) 157 and the printed circuit board may be transmitted to the (2-1)-th connection line 122a via the (2-3)-th connection line 122c and the (2-2)-th connection line 122b.

The (2-4)-th connection line 122d may be disposed on the second insulating layer 115b. The (2-4)-th connection line 122d may be disposed in the second non-display area NA2. The (2-4)-th connection line 122d may be electrically connected to the (2-3)-th connection line 122b via a contact hole of the second organic insulating layer 115b. Accordingly, signals from the flexible film FF and the printed circuit board may be transmitted to the (2-1)-th connection line 122a via the (2-4)-th connection line 122d, the (2-3)-th connection line 122c, and the (2-2)-th connection line 122b.

Each of the plurality of first connection lines 121 and the plurality of second connection lines 122 may be made of a conductive material having excellent ductility or various conductive materials used in the display area AA. For example, the second connection line 122, a portion of which is disposed in the bending area BA, may be made of a conductive material having excellent ductility, such as gold (Au), silver (Ag), or aluminum (Al). However, embodiments of the present disclosure are not limited thereto. In another example, each of the plurality of first connection lines 121 and the plurality of second connection lines 122 may be made of molybdenum (Mo), chromium (Cr), titanium (Ti), nickel (Ni), neodymium (Nd), copper (Cu), an alloy of silver (Ag) and magnesium (Mg), or an alloy thereof. However, embodiments of the present disclosure are not limited thereto.

A third insulating layer 115c may be disposed on the plurality of first connection lines 121 and the plurality of second connection lines 122. The third insulating layer 115c may be disposed in the remaining area except for the bending area BA. However, embodiments of the present disclosure are not limited thereto. The third insulating layer 115c may be disposed in the display area AA, the first non-display area NA1, and the second non-display area NA2. A portion of the third insulating layer 115c in the bending area BA may be removed. The third insulating layer 115c may be made of an organic insulating material. However, embodiments of the present disclosure are not limited thereto. For example, the third insulating layer 115c may be made of a photo resist, polyimide (PI), or a photo acryl-based material. However, embodiments of the present disclosure are not limited thereto.

In the display area AA, a plurality of banks BNK may be disposed on the third insulating layer 115c. The plurality of banks BNK may be disposed to overlap the plurality of sub-pixels, respectively. One or more light-emitting elements ED of the same type may be disposed on each of the plurality of banks BNK.

According to the present disclosure, the bank BNK may be disposed in each of the plurality of sub-pixels 130, 140, and 150. Each of the plurality of light-emitting elements ED is seated on each of the plurality of banks BNK. Each of the plurality of banks BNK may guide a position of each of the plurality of light-emitting elements ED in a transfer process of transferring the plurality of light-emitting elements ED in manufacturing the display device 1000. In the transfer process of the plurality of light-emitting elements ED, the plurality of light-emitting elements ED may be transferred onto the plurality of banks BNK. The plurality of banks BNK may be bank patterns or structures. However, embodiments of the disclosure are not limited thereto.

The bank BNK of the first sub-pixel 130, the bank BNK of the second sub-pixel 140, and the bank BNK of the third sub-pixel 150 may be spaced apart from each other. The bank BNK of the first sub-pixel 130, the bank BNK of the second sub-pixel 140, and the bank BNK of the third sub-pixel 150 may be separated from each other. Accordingly, the banks BNK of the first sub-pixel 130, the second sub-pixel 140, and the third sub-pixel 150 to which different types of light-emitting elements ED are respectively transferred may be easily distinguished from each other.

In the display area AA, the plurality of signal lines TL may be disposed on the third insulating layer 115c. The plurality of signal lines TL may be disposed in an area between adjacent ones of the plurality of banks BNK. For example, the plurality of signal lines TL may be disposed adjacent to one of the plurality of banks BNK.

The plurality of contact electrodes CCE may be disposed on the third insulating layer 115c in the display area AA. The plurality of contact electrodes CCE may supply the cathode voltage from the pixel driving circuit PD to the second electrode CE2.

The first electrode CE1 may be disposed on the bank BNK. For example, the first electrode CE1 may be disposed to extend from the adjacent signal line TL toward the upper portion of the bank BNK. The first electrode CE1 may be disposed on an upper surface of the bank BNK and a side surface of the bank BNK. For example, the first electrode CE1 may be disposed to extend from the signal line TL on the upper surface of the third insulating layer 115c to the side surface of the bank BNK and the upper surface of the bank BNK.

The second electrode CE2 may be disposed in each of the plurality of sub-pixels SP. The second electrode CE2 may be disposed on the light-emitting element ED. The second electrode CE2 may be electrically connected to the pixel driving circuit PD via a plurality of contact electrodes CCE.

For example, the second electrode CE2 may be electrically connected to the cathode electrode 135 of the light-emitting element ED to transmit the cathode voltage from the pixel driving circuit PD to the light-emitting element ED. The same cathode voltage may be applied to the second electrodes CE2 of the plurality of sub-pixels SP. For example, the same voltage may be applied to the second electrodes CE2 of the plurality of sub-pixels and the cathode electrode 135 of the light-emitting element ED. Accordingly, the second electrode CE2 may be a common electrode. However, embodiments of the present disclosure are not limited thereto.

At least some of the plurality of sub-pixels may share the second electrode CE2 with each other. At least some of the second electrodes CE2 of the plurality of sub-pixels SP may be electrically connected to each other. As the same voltage is applied to the second electrodes CE2, the second electrode CE2 may be shared by the at least some sub-pixels. For example, the second electrodes CE2 of at least some pixels PX among the plurality of pixels PX disposed in the same row may be connected to each other. For example, one second electrode CE2 may be disposed in the plurality of pixels PX. One second electrode CE2 may be disposed every n sub-pixels.

For example, some of the respective second electrodes CE2 of the plurality of sub-pixels SP may be spaced apart or isolated from each other. For example, the second electrode CE2 connected to the pixels PX of an n-th row and the second electrode CE2 connected to the pixels PX of an (n+1)-th row may be spaced apart or isolated from each other. For example, adjacent ones of the plurality of second electrodes CE2 may be arranged to be spaced apart from each other while the plurality of communication lines NL extending in the row direction are disposed therebetween. Accordingly, the number of the plurality of sub-pixels may be greater than the number of the plurality of second electrodes CE2. In another example, all of the second electrodes CE2 of the plurality of sub-pixels may be connected to each other, such that only one second electrode CE2 may be disposed on the substrate 110. However, embodiments of the present disclosure are not limited thereto.

Each of the plurality of second electrodes CE2 may be made of a transparent conductive material. However, embodiments of the present disclosure are not limited thereto. Each of the plurality of second electrodes CE2 may be made of a transparent conductive material, and may allow light emitted from the light-emitting element ED to be directed upwardly of the second electrode CE2. For example, the second electrode CE2 may be made of a transparent conductive material such as Indium Tin Oxide (ITO), Indium Zinc Oxide (IZO), Indium Gallium Zinc Oxide (IGZO), etc. However, embodiments of the present disclosure are not limited thereto.

The first electrode CE1 may act as a lower electrode of the light-emitting element ED, and the second electrode CE2 may act as an upper electrode of the light-emitting element ED.

The plurality of contact electrodes CCE may be disposed on the substrate 110. For example, the plurality of contact electrodes CCE may be disposed to be spaced apart from the plurality of banks BNK and the plurality of signal lines TL. Each of the plurality of second electrodes CE2 may overlap at least one contact electrode CCE. For example, one second electrode CE2 may overlap the plurality of contact electrodes CCE.

For example, each of the plurality of contact electrodes CCE may be electrically connected to each of the plurality of second electrodes CE2. Each of the plurality of contact electrodes CCE may be disposed between the substrate 110 and each of the plurality of second electrodes CE2 to transmit the cathode voltage from the pixel driving circuit PD to each of the second electrodes CE2.

For example, when the micro LED is used as the light-emitting element ED, a plurality of micro LEDs may be formed on a wafer, and the micro LEDs may be transferred to the substrate 110 of the display device 1000 to manufacture the display device 1000. Various defects may occur in the process of transferring the plurality of light-emitting elements ED having a fine size from the wafer to the substrate 110. For example, a non-transfer defect in which the light-emitting element ED is not transferred may occur in some sub-pixels, and an incorrect position defect in which the light-emitting element ED is transferred out of the correct position due to an alignment error may occur in some further sub-pixels. In addition, the transfer process is normally performed, while the transferred light-emitting element ED itself may be defective. Therefore, the plurality of light-emitting elements ED of the same type may be transferred to one sub-pixel in consideration of the defect in the transfer process of the plurality of light-emitting elements ED. The lighting test of the plurality of light-emitting elements ED is performed, and only one light-emitting element ED that has been finally determined to be normal or non-defective may be used.

Each of the plurality of light-emitting elements 130, 140, and 150 may have a groove defined in a center of a bottom portion, and may be bonded to the first electrode CE1 via the solder pattern SDP that fills the groove and protrudes downwardly beyond a bottom surface of each of the plurality of light-emitting elements 130, 140, and 150.

According to the present disclosure, the solder pattern SDP may be disposed on the first electrode CE1 and in each of the plurality of sub-pixels. The solder pattern SDP may bond the light-emitting element ED to the first electrode CE1. The first electrode CE1 and the light-emitting element ED may be electrically connected to each other via eutectic bonding using the solder pattern SDP. However, embodiments of the present disclosure are not limited thereto. For example, when the solder pattern SDP is made of indium (In) and the anode electrode 134 of the light-emitting element ED is made of gold (Au), heat and pressure may be applied thereto in the transfer process of the light-emitting element ED to bond the solder pattern SDP and the anode electrode 134 to each other. Via the eutectic bonding, the light-emitting element ED may be bonded to the solder pattern SDP and the first electrode CE1 without a separate adhesive. For example, the solder pattern SDP may be made of indium (In), tin (Sn), or an alloy thereof. However, embodiments of the present disclosure are not limited thereto. For example, the solder pattern SDP may be embodied as a bonding pad, a bonding pad, etc. However, embodiments of the present disclosure are not limited thereto.

According to the present disclosure, a passivation layer 116 may be disposed on the plurality of signal lines TL, the plurality of first electrodes CE1, the plurality of contact electrodes CCE, and the third insulating layer 115c. For example, the passivation layer 116 may be disposed in the display area AA, the first non-display area NA1, and the second non-display area NA2. A portion of the passivation layer 116 disposed in the bending area BA may be removed. A portion of the passivation layer 116 covering the plurality of pad electrodes PE in the second non-display area NA2 may be removed. Since the passivation layer 116 is disposed to cover the remaining area except for the bending area BA, an area of the plurality of pad electrodes PE, and an area of the solder pattern SDP, penetration of moisture or impurities flowing into the light-emitting element ED may be reduced. For example, the passivation layer 116 may be formed as a single layer or multiple layers made of silicon oxide (SiOx) or silicon nitride (SiNx). However, embodiments of the present disclosure are not limited thereto. For example, the passivation layer 116 may be embodied as a protective layer, an insulating layer, etc. However, embodiments of the present disclosure are not limited thereto. For example, the passivation layer 116 may have a hole defined therein exposing the solder pattern SDP.

In each of the plurality of sub-pixels, the light-emitting element ED may be disposed on the solder pattern SDP. The first light-emitting element 130 may be disposed in the first sub-pixel SP1. The second light-emitting element 140 may be disposed in the second sub-pixel SP2. The third light-emitting element 150 may be disposed in the third sub-pixel SP3. Each of the plurality of light-emitting elements 130, 140, and 150 may be embodied as a micro light-emitting element.

The light-emitting element ED may be formed on a silicon wafer using a Metal Organic Chemical Vapor Deposition (MOCVD) method, a Chemical Vapor Deposition (CVD) method, a Plasma-Enhanced Chemical Vapor Deposition (PECVD) method, a Molecular Beam Epitaxy (MBE) method, a Hydride Vapor Phase Epitaxy (HVPE) method, or sputtering method. However, embodiments of the present disclosure are not limited thereto.

The optical insulating layer 117 may include a first optical layer 117a, a second optical layer 117b, and a third optical layer 117c.

According to the present disclosure, the first optical layer 117a surrounding the plurality of light-emitting elements ED may be disposed in the display area AA. For example, the first optical layer 117a may be disposed to cover the plurality of light-emitting elements ED and the bank BNK in the areas of the plurality of sub-pixels. For example, the first optical layer 117a may cover the bank BNK, a portion of the passivation layer 116, and an area between adjacent ones of the plurality of light-emitting elements ED. The first optical layer 117a may be disposed in or cover an area between adjacent ones of the plurality of light-emitting elements ED included and an area between adjacent ones of the plurality of banks BNK in one pixel PX. For example, the first optical layer 117a may extend in the first direction X and the first optical layers 117a may be spaced apart from each other in the second direction Y. For example, the first optical layer 117a may be disposed between the passivation layer 116 and the second electrode CE2 so as to surround the side of each of the light-emitting element ED and the bank BNK. However, embodiments of the present disclosure are not limited thereto. For example, the first optical layer 117a may act as a diffusion layer, a sidewall diffusion layer, etc. However, embodiments of the present disclosure are not limited thereto.

The first optical layer 117a may include an organic insulating material in which fine particles are dispersed. However, embodiments of the present disclosure are not limited thereto. For example, the first optical layer 117a may be made of siloxane in which fine metal particles such as titanium dioxide (TiO₂) particles are dispersed. However, embodiments of the present disclosure are not limited thereto. Light from the plurality of light-emitting elements ED may be scattered by the fine particles dispersed in the first optical layer 117a and then emitted out of the display device 1000. Accordingly, the first optical layer 117a may improve extraction efficiency of light emitted from the plurality of light-emitting elements ED.

For example, the first optical layer 117a may be disposed in each of the plurality of pixels PX, or may be commonly disposed in some pixels PX arranged in the same row. However, embodiments of the present disclosure are not limited thereto. For example, the first optical layer 117a may be disposed in each of the plurality of pixels PX, or the plurality of pixels PX may share one first optical layer 117a with each other. In another example, each of the plurality of sub-pixels SP may separately include the first optical layer 117a. However, embodiments of the present disclosure are not limited thereto.

According to the present disclosure, the second optical layer 117b may be disposed on the passivation layer 116 and in the display area AA. For example, the second optical layer 117b may be disposed to surround the first optical layer 117a. For example, the second optical layer 117b may be in contact with a side surface of the first optical layer 117a. For example, the second optical layer 117b may be disposed in an area between adjacent ones of the plurality of pixels PX. However, embodiments of the present disclosure are not limited thereto. For example, the second optical layer 117b may act as a diffusion layer, a diffusion layer window, a window diffusion layer, etc. However, embodiments of the present disclosure are not limited thereto.

The second optical layer 117b may be made of an organic insulating material. However, embodiments of the present disclosure are not limited thereto. The second optical layer 117b may be made of the same material as that of the first optical layer 117a. However, embodiments of the present disclosure are not limited thereto. For example, the first optical layer 117a may include fine particles, and the second optical layer 117b may not include fine particles. For example, the second optical layer 117b may be made of siloxane. However, embodiments of the present disclosure are not limited thereto.

For example, a thickness of the first optical layer 117a may be smaller than a thickness of the second optical layer 117b. However, embodiments of the present disclosure are not limited thereto. Accordingly, in a cross-sectional view of the device, an area in which the first optical layer 117a is disposed may include a concave portion recessed downwardly beyond an upper surface of the second optical layer 117b.

According to the present disclosure, the second electrode CE2 may be disposed on the first optical layer 117a and the second optical layer 117b. For example, the second electrode CE2 may be electrically connected to the plurality of contact electrodes CCE via a contact hole of the second optical layer 117b. For example, the second electrode CE2 may be disposed on the plurality of light-emitting elements ED. For example, the second electrode CE2 may include a transparent conductive oxide such as indium tin oxide (ITO) or indium zinc oxide (IZO). However, embodiments of the present disclosure are not limited thereto. For example, the second electrode CE2 may be disposed to be in contact with the cathode electrode 135. For example, the second electrode CE2 may overlap the first optical layer 117a. For example, the second electrode CE2 may cover a flat upper surface of an outer portion of the first optical layer 117a.

The second electrode CE2 may continuously extend in the first direction of the substrate 110. Accordingly, the plurality of pixels PX arranged in the first direction of the substrate 110 may be commonly connected to the second electrode CE2. For example, the second electrode CE2 may be commonly connected to the plurality of pixels PX.

According to the present disclosure, the second electrode CE2 may continuously extend across the first optical layer 117a, the second optical layer 117b, and the plurality of light-emitting elements ED. An area in which the first optical layer 117a is disposed may include the concave portion recessed downwardly beyond the upper surface of the second optical layer 117b. Accordingly, since a first portion of the second electrode CE2 disposed on the first optical layer 117a is disposed along and on the concave portion, a vertical level of the first portion may be lower than a vertical level of a second portion of the second electrode CE2 disposed on the second optical layer 117b.

The third optical layer 117c may be disposed on the second electrode CE2. The third optical layer 117c may be disposed to overlap the plurality of light-emitting elements ED and the first optical layer 117a. Since the third optical layer 117c is disposed on the second electrode CE2 and the plurality of light-emitting elements ED, a mura that may occur in some of the plurality of light-emitting elements ED may be suppressed. For example, when the plurality of light-emitting elements ED are transferred onto the substrate 110 of the display device 1000, an area in which spacings between adjacent ones of the plurality of light-emitting elements ED are not uniform may occur due to process variations or etc. When the spacings between adjacent ones of the plurality of light-emitting elements ED are non-uniform, respective light emission areas of the plurality of light-emitting elements ED may be non-uniformly arranged, and thus, the mura may be visually recognized by the user. Accordingly, since the third optical layer 117c configured to uniformly diffuse light is formed on top of the plurality of light-emitting elements ED, a phenomenon that the light emitted from some light-emitting elements ED is visible as the mura to the user may be suppressed. Accordingly, the light emitted from the plurality of light-emitting elements ED may be uniformly diffused by the third optical layer 117c and then be extracted out of the display device 1000, such that the luminance uniformity of the display device 1000 may be improved.

The third optical layer 117c may be made of an organic insulating material in which fine particles are dispersed. However, an embodiment of the present disclosure is not limited thereto. For example, the third optical layer 117c may be made of siloxane in which fine metal particles such as titanium dioxide (TiO₂) particles are dispersed. However, embodiments of the present disclosure are not limited thereto. For example, the third optical layer 117c may be made of the same material as that of the first optical layer 117a. However, embodiments of the present disclosure are not limited thereto. For example, the third optical layer 117c may act as a diffusion layer, an upper surface diffusion layer, etc. However, embodiments of the present disclosure are not limited thereto.

According to the present disclosure, light from the plurality of light-emitting elements ED may be scattered by the fine particles dispersed in the third optical layer 117c and be emitted out of the display device 1000. The third optical layer 117c may evenly mix light beams respectively emitted from the plurality of light-emitting elements ED with each other to further improve luminance uniformity of the display device 1000. In addition, light extraction efficiency of the display device 1000 may be improved by the light being scattered from the plurality of fine particles, and accordingly, the display device 1000 may operate at a low power level.

A black matrix BM may be disposed on the second electrode CE2, the first optical layer 117a, the second optical layer 117b, and the third optical layer 117c and in the display area AA. For example, the black matrix BM may fill a contact hole of the second optical layer 117b. Since the black matrix BM is constructed to cover the display area AA, the black matrix may reduce color mixing between light beams from the plurality of sub-pixels and may prevent or reduce external light reflection. For example, since the black matrix BM is also disposed in the contact hole via which the second electrode CE2 and the contact electrode CCE are connected to each other, light leakage between adjacent ones of the plurality of sub-pixels may be prevented or reduced.

For example, the black matrix BM may be made of an opaque material. However, embodiments of the present disclosure are not limited thereto. For example, the black matrix BM may be made of an organic insulating material to which a black pigment or a black dye is added. However, embodiments of the present disclosure are not limited thereto.

A cover layer 118 may be disposed on the black matrix BM and in the display area AA. The cover layer 118 may protect the components under the cover layer 118. For example, the cover layer 118 may be made of an organic insulating material. However, embodiments of the present disclosure are not limited thereto. For example, the cover layer 118 may be made of a photoresist, polyimide (PI), or a photo acryl-based material. However, embodiments of the present disclosure are not limited thereto. For example, the cover layer 118 may be embodied as an overcoat layer, an insulating layer, etc. However, embodiments of the present disclosure are not limited thereto.

The polarizing layer 293 may be disposed on the cover layer 118 via a first adhesive layer 291. The cover member 155 may be disposed on the polarizing layer 293 via a second adhesive layer 295. For example, each of the first adhesive layer 291 and the second adhesive layer 295 may include an OCA (Optically clear adhesive), an OCR (Optically clear resin), a PSA (Pressure sensitive adhesive), etc. However, embodiments of the present disclosure are not limited thereto.

According to the present disclosure, the plurality of pad electrodes PE may be disposed on the third insulating layer 115c and in the second non-display area NA2. For example, at least a portion of each of the plurality of pad electrodes PE may not be covered with the passivation layer 116 so as to be exposed. For example, the plurality of pad electrodes PE may be electrically connected to the (2-4)-th connection line 122c via a contact hole of the third insulating layer 115d.

An adhesive layer ACF may be disposed on the plurality of pad electrodes PE. The adhesive layer ACF may be an adhesive layer in which conductive balls are dispersed in an insulating material. However, embodiments of the present disclosure are not limited thereto. When heat or pressure is applied to the adhesive layer ACF, the conductive balls may be electrically connected to each other in an area to which the heat or pressure has been applied such that the adhesive layer ACF may be conductive. The adhesive layer ACF may be disposed between the plurality of pad electrodes PE and the flexible circuit board (or flexible film) 157 to attach or bond the flexible circuit board (or flexible film) 157 to the plurality of pad electrodes PE. For example, the adhesive layer ACF may be embodied as an anisotropic conductive film (ACF). However, embodiments of the present disclosure are not limited thereto.

The flexible circuit board (or flexible film) 157 may be disposed on the adhesive layer ACF. The flexible circuit board (or flexible film) 157 may be electrically connected to the plurality of pad electrodes PE via the adhesive layer ACF. Accordingly, the signals output from the flexible circuit board (or flexible film) 157 and the printed circuit board may be transmitted to the pixel driving circuit PD of the display area AA via the plurality of pad electrodes PE, the (2-4)-th connection line 122d, the (2-3)-th connection line 122c, the (2-1)-th connection line 122b, and the (2-1)-th connection line 122a.

As shown in FIG. 4, the second back plate BP2 may have a flat portion that is not bent and corresponds to the display area AA. A bending stress relief hole (Pre-Bend Stress Hole) PH may be formed in the flat portion.

In this regard, the bending stress relief hole PH may be formed to extend through, for example, the second back plate BP 2 made of a metal material in a cut-out manner. Accordingly, the bending stress relief hole PH may be referred to as a cut-out hole.

The curved cover member 155 has a cavity defined therein. An optical adhesive layer 295 is disposed on a bottom surface of the curved cover member 155 defining the cavity, an optical control layer 293 is disposed on the optical adhesive layer 295, and the display panel 100 is disposed on the optical control layer 293. The optical adhesive layer 295 may include an optical clear adhesive (OCA), and the optical control layer 293 may include, for example, a polarization layer (POL).

In addition, a second adhesive layer AD2 is disposed on the display panel 100, the first back plate BP1 is disposed on the second adhesive layer AD2, a first adhesive layer AD1 is disposed on the first back plate BP1, the second back plate BP2 is disposed on the first adhesive layer AD1, and the circuit boards 157 and 160 and a bending protection layer MCL are disposed on the second back plate BP2.

When an entirety of the second back plate BP2 is unfolded in a flat state before being bent, the bending stress relief hole PH may be formed in the flat surface thereof at a position thereof corresponding to or vertically overlapping an inner edge of a flange 155f.

When a width a2 of an upper surface of the flange 155f of the curved cover member 155 in contact with a bent portion 100b of the display panel is, for example, 0.4 millimeters (mm), an inorganic film-free area a1 of the bent portion 100b of the display panel may be 1.6 millimeters (mm). In a state in which the display panel is not bent, the bent portion 100b of the display panel may overlap the first back plate BP1 by 0.1 millimeters (mm), a section of the bent portion 100b therefrom to a contact position with the second back plate BP2 may be 0.7 millimeters (mm), and a section thereof therefrom to the bending stress relief hole PH may be 0.4 millimeters (mm).

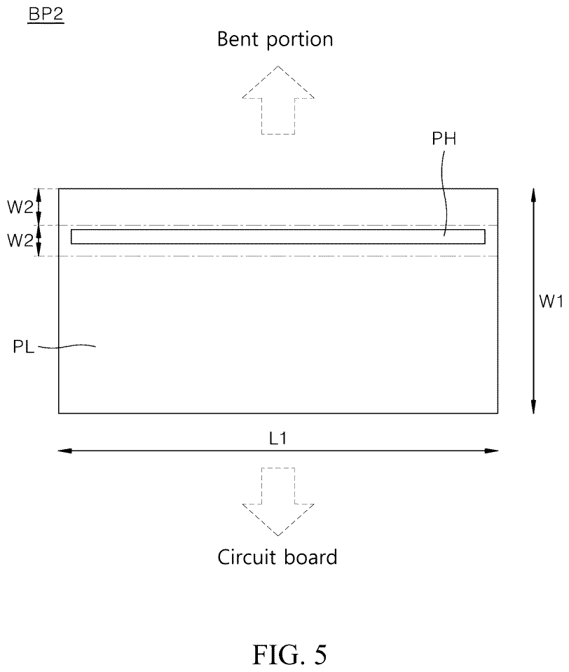

As illustrated in FIG. 5, the second back plate BP2 may be embodied as a plate PL having a predefined first width W1 and a predefined first length L1. The bending stress relief hole PH defined in the second back plate BP2 may be positioned to be closer to a side at which the plate PL is bent than to a side of the plate PL facing the circuit board 160. FIG. 5 is a diagram illustrating an example in which the bending stress relief hole is formed in the second back plate according to an embodiment of the disclosure. In the second back plate BP, the first width W1 may be 3.5 millimeters (mm), and the first length L1 may be 17.0 millimeters (mm). This is only an example. Although the bending stress relief hole PH has been illustrated as having a rectangular shape in a plan view, an embodiment of the present disclosure is not limited thereto. The bending stress relief hole PH may be spaced apart from an upper side (one side in a column direction) of the plate PL (that is, the side at which the plate PL is bent) by a second width W2 and may have a width smaller than the second width W2. However, embodiments of the disclosure are not limited thereto. For example, the bending stress relief hole PH may have a width of 0.2 millimeters (mm) and a length of 16.2 millimeters (mm). The second width W2 may be 0.4 millimeters (mm).

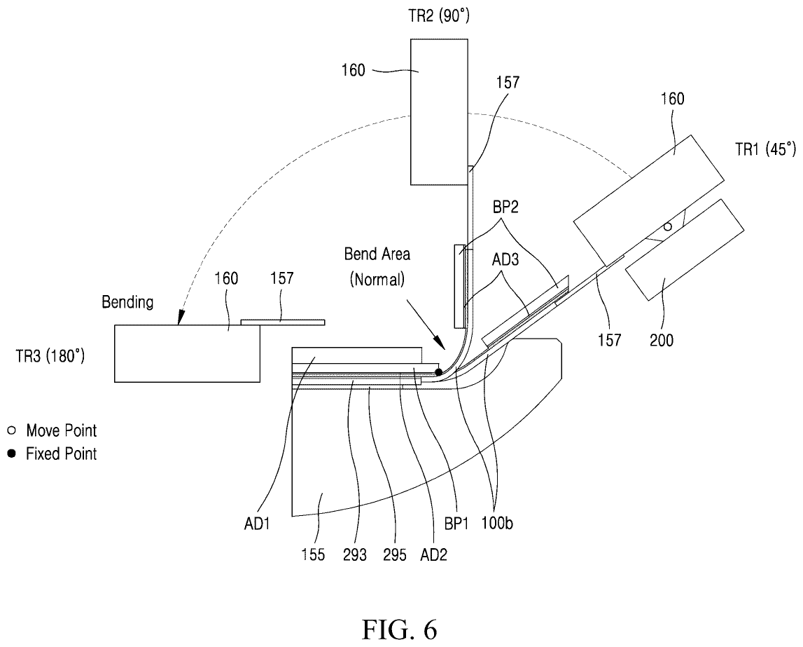

FIG. 6 is a diagram illustrating a bending process of a display panel and a second back plate according to an embodiment of the present disclosure.

As shown in FIG. 6, the second back plate BP2 disposed on the bent portion 100b of the display panel 100 according to an embodiment of the present disclosure may be inclined at 45 degrees) (° at an initial turning radius TR1.

In this regard, the bent portion 100b of the display panel and the printed circuit board 160 are connected to each other via the flexible circuit board 157, and a suction means 200 is attached to a rear surface of the printed circuit board 160 in a suctioning manner.

The second back plate BP2 is attached to the bent portion 100b of the display panel via a third adhesive layer AD3.

The second back plate BP2 rotates according to the movement of the suction means 200 and thus is inclined or bent at 90 degrees) (° at a second turning radius TR2.

The second back plate BP2 may pivot around an end of the first back plate BP1 in the bendable area BA as a fixed point. A central point of the printed circuit board 160 attached to the suction means 200 may rotate such that the second back plate BP2 may pivot.

The second back plate BP2 is bent in the bendable area BA by the suction means 200 so as to be bent at 180 degrees) (° at a third turning radius TR3.

In the conventional display device 1000, there is an uncontrollable area in floating in a bending process, reverse bending in which the printed circuit board 160 is tilted backwards, compressed stress of the curved cover member 155 in the sucked state, and substate press-fit (pulling stress) in a roller application process, and the like, and thus periodic, repetitive, random damage due to external force occurs.

However, in the display device 1000 according to an embodiment of the present disclosure, the bending stress relief hole PH is formed in the second back plate BP 2 bonded to the bent portion 100b of the display panel via the third adhesive layer AD 3. Thus, when the display panel 100 is unfolded before the bending, the edge 155e of the flange 155f of the curved cover member 155 comes into contact with the bending stress relief hole PH, thereby relieving the bending stress.

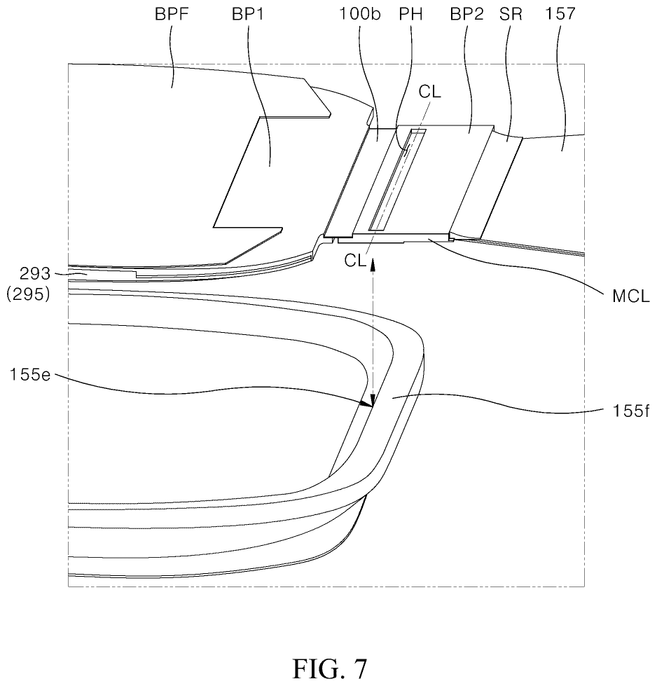

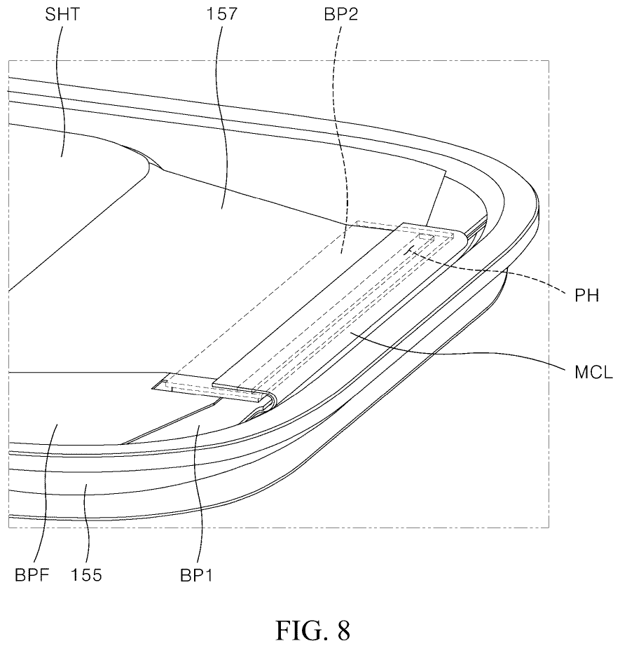

FIG. 7 is a diagram illustrating an example in which a flange edge of a cover member is vertically aligned with a bending stress relief hole before bending of a second back plate according to an embodiment of the disclosure. FIG. 8 is a diagram illustrating a state after the second back plate is bent according to an embodiment of the present disclosure.

As shown in FIG. 7, a center line CL of the bending stress relief hole PH defined in the second back plate BP2 according to an embodiment of the present disclosure vertically overlaps the flange edge 155e as an inner edge of the flange 155f of the curved cover member 155 before the bending in a state of being disposed on the bent portion 100b of the display panel.

That is, the center line CL of the bending stress relief hole PH extending along a longitudinal direction of the second back plate BP2 and located at a center in the width direction of the bending stress relief hole PH may be vertically aligned with or vertically overlap the flange edge 155e as the inner edge of the flange 155f of the curved cover member 155.

The bent portion 100b of the display panel includes one portion disposed under the first back plate BP1, and the other portion which extends outwardly therefrom, and is disposed under the second back plate BP2.

The bending protection layer MCL is disposed under the second back plate BP2, and a soft resin SR is disposed outwardly of the bending protection layer MCL, and the flexible circuit board 157 is disposed outwardly of the soft resin SR.

The optical control layer 293 and the optical adhesive layer 295 may be disposed under the first back plate BP1.

A black protection film BPF may be disposed on the first back plate BP1.

Therefore, even when the second back plate BP2 comes into contact with the flange 155f of the curved cover member 155 before the bending, the flange edge 155e is inserted into the bending stress relief hole PH, so that stress generated during the contact may also be relieved.

As shown in FIG. 8, when the first back plate BP1 is seated on the inner surface of the curved cover member 155, and the second back plate BP2 and the bent portion 100b of the display panel are bent, the bending stress may be relieved by the bending stress relief hole PH.

In this regard, in the cavity defined in the curved cover member 155, the bending protection layer MCL may be disposed on the outer area of the second back plate BP 2 and an outer surface of the bent portion 100b of the display panel. In an area inwardly of the bending protection layer MCL, the flexible circuit board 157 may be disposed on the black protection film BPF, and a shield tape SHT may be disposed thereon.

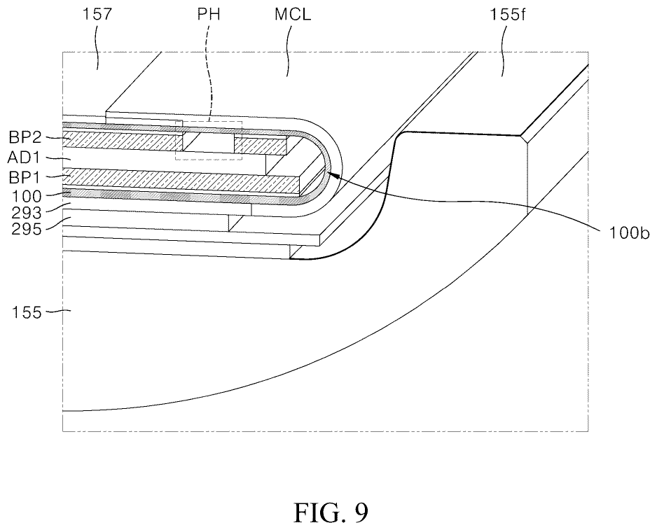

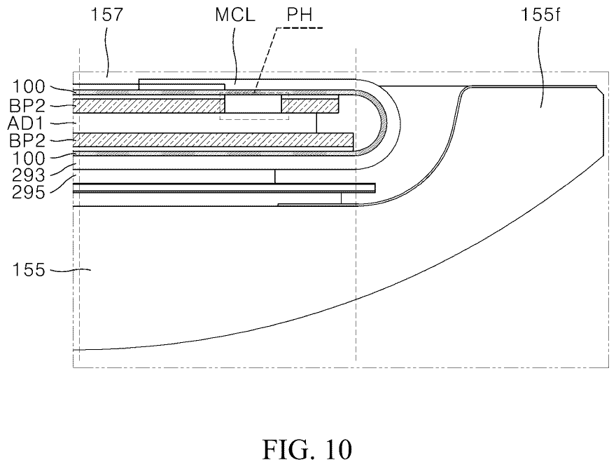

FIG. 9 is a perspective view illustrating a state in which the second back plate is seated in the cavity defined in the curved cover member after the display panel is bent according to an embodiment of the disclosure. FIG. 10 is a cross-sectional view illustrating a state in which the second back plate is seated in the cavity defined in the curved cover member after the display panel is bent according to an embodiment of the disclosure.

As shown in FIGS. 9 and 10, the second back plate BP2 according to an embodiment of the disclosure may be seated inside the cavity of the curved cover member 155 in a state in which the display panel on which the second back plate BP2 is disposed is bent.

In this regard, the optical adhesive layer 295 is disposed on the bottom surface of the curved cover member 155 defining the cavity, the optical control layer 293 is disposed on the optical adhesive layer 295, and the display panel 100 is disposed on the optical control layer 293.

The display panel 100 extends toward the flange 155f of the curved cover member 155 and then is bent, and then the remaining portion (the bent portion 100b of the display panel) thereof is located on the upper surface of the second back plate BP2.

The second adhesive layer AD2 is disposed on the display panel 100, the first back plate BP1 is disposed on the second adhesive layer AD2, the first adhesive layer AD1 is disposed on the first back plate BP1, the second back plate BP2 is disposed on the first adhesive layer AD1, the bent portion 100b of the display panel is disposed on the second back plate BP2. The circuit board 157 and the bending protection layer MCL are disposed on the bent portion 100b of the display panel.

The display panel 100 may include a first flat portion, a second flat portion facing the first flat portion, and a curved portion which extends from the first flat portion and is bent backwardly in the bendable area BA, and is positioned between the first flat portion and the second flat portion.

The first back plate BP1 and the second back plate BP2 may be respectively located on the rear surface of the first flat portion and the rear surface of the second flat portion of the display panel 100.

In this regard, the bending stress relief hole PH may be formed in the second back plate BP2. The second back plate BP2 has the flat portion, and the bending stress relief hole PH may be formed in the flat portion.

Accordingly, the second back plate BP2 and the bending stress relief hole PH may be disposed on the first adhesive layer AD1, and the bent portion 100b of the display panel may be disposed on the second back plate BP2 and the bending stress relief hole PH.

The bending stress relief hole PH may not overlap the circuit board 157 and 160, but may overlap the bending protection layer MCL.

In the stacked structure of FIGS. 9 and 10, in a state in which the optical adhesive layer 295 to the circuit board 157 and 160 and the bending protection layer MCL are sequentially and upwardly stacked on the bottom surface of the curved cover member 155 defining the cavity, the upper surface of each of the circuit board 157 and 160 and the bending protection layer MCL as the uppermost layer may be coplanar with the upper surface of the flange 155f.

Alternatively, in a state in which the optical adhesive layer 295 to the circuit board 157 and 160 and the bending protection layer MCL are sequentially and upwardly stacked on the bottom surface of the curved cover member 155 defining the cavity, the upper surface of the flange 155f may be disposed at a position lower than a position of the upper surface of each of the circuit board 157 and 160 and the bending protection layer MCL as the uppermost layer.

The bending stress relief hole PH may be formed to have a length smaller than the length of the second back plate BP 2. For example, when the length of the second back plate BP2 is 17.0 millimeters (mm), the bending stress relief hole PH may have a length of 16.2 millimeters (mm).

The bending stress relief hole PH may be formed in the second back plate BP2 embodied as the plate PL having a predefined width W1 and a predefined length L1 and may be positioned in an area corresponding to the non-display area NA of the display panel 100. For example, the length of the plate PL may be 17.0 millimeters (mm), and the width of the plate PL may be 3.5 millimeters (mm).

In this regard, the bending stress relief hole PH may have a width of 0.2 millimeters (mm) when the width of the plate PL is 3.5 millimeters (mm). However, embodiments of the disclosure are not limited thereto. For example, the width of the bending stress relief hole PH may be appropriately set to be in a range of 200 micrometers (μm) to 0.2 millimeters (mm), according to the model of each display device.

The second back plate BP 2 having the bending stress relief hole PH defined therein may include at least one of polyimide (PI), polyethylene naphthalate (PEN), polyethylene terephthalate (PET), polymers, and a combination of the polymers.

Therefore, when the second back plate BP2 according to an embodiment of the present disclosure together with the display panel 100 and the bending protection layer MCL are bent in the bendable area BA, the stress and strain according to the present approach may be significantly reduced from 16.3% as a value in a conventional approach to 8.6%.

In addition, when the second back plate BP 2 according to an embodiment of the present disclosure together with the display panel 100 and the bending protection layer MCL are bent in the bendable area BA, the stress applied to the inorganic film in the present approach is greatly reduced from 231 megapascals (Mpa) as a value in a conventional approach to 17 megapascals Mpa, thereby almost removing the stress.

As described above, according to an embodiment of the present disclosure, a display device that prevents or suppresses damage to an inorganic layer or a data line layer during a bending process of a display panel may be provided.

In addition, according to an embodiment of the present disclosure, a display device capable of relieving a bending stress generated during a bending process of the display panel due to the bending stress relief hole defined in the support member supporting the display panel, thereby preventing or suppressing damage to the display panel may be provided.

The display devices according to various aspects and embodiments of the present disclosure may be described as follows.

One aspect of the present disclosure provides a display device comprising: a display panel including a display area, a non-display area, and a bendable area; a first back plate and a second back plate supporting the display panel; and a curved cover member having a cavity having a predetermined depth defined therein, wherein the first back plate and the second back plate are seated in the cavity, wherein the curved cover member has a flange having a predetermined height and disposed outwardly of the cavity, wherein a general shape of the curved cover member is a sprue shape, wherein the display panel has a bent portion in the bendable area, and wherein the second back plate includes a flat portion corresponding to the display area, and a bending stress relief hole is formed in the flat portion.

In accordance with some embodiments, in the cavity, an optical adhesive layer is disposed on an bottom surface of the curved cover member defining the cavity, an optical control layer is disposed on the optical adhesive layer, the display panel is disposed on the optical control layer, a second adhesive layer is disposed on the display panel, the first back plate is disposed on the second adhesive layer, a first adhesive layer is disposed on the first back plate, the second back plate is disposed on the first adhesive layer, a circuit board and a bending protection layer are disposed on the second back plate.

In accordance with some embodiments, in a state in which the display panel is in a flat state before the display panel is bent, the bending stress relief hole is positioned at a position of the flat portion vertically aligned with an inner edge of the flange.

In accordance with some embodiments, the second back plate is embodied as a plate having a predetermined width and a predetermined length, wherein the plate has first and second sides opposite to each other in the width direction, wherein the first side of the plate is close to a portion of the display panel to be bent, and the second side of the plate is close to a circuit board, wherein the bending stress relief hole is closer to the first side than to the second side.

In accordance with some embodiments, the bending stress relief hole has a rectangular shape in a plan view of the display device.

In accordance with some embodiments, the bending stress relief hole has a center line extending along a longitudinal direction of the second back plate, wherein the center line is positioned at a center in the width direction of the bending stress relief hole, wherein the center line is vertically aligned with an inner edge of the flange of the curved cover member.

In accordance with some embodiments, the bending stress relief hole vertically non-overlaps the circuit board, but vertically overlaps the bending protection layer.

In accordance with some embodiments, in a state in which the optical adhesive layer to the circuit board and the bending protection layer are sequentially and upwardly stacked on the bottom surface of the curved cover member defining the cavity, an upper surface of each of the circuit board and the bending protection layer as an uppermost layer is coplanar with an upper surface of the flange.

In accordance with some embodiments, in a state in which the optical adhesive layer to the circuit board and the bending protection layer are sequentially and upwardly stacked on the bottom surface of the curved cover member defining the cavity, a vertical level of an upper surface of the flange is lower than a vertical level of an upper surface of each of the circuit board and the bending protection layer as an uppermost layer.

In accordance with some embodiments, the bending stress relief hole has a length smaller than a length of the second back plate.

In accordance with some embodiments, the second back plate is embodied as a plate having a predetermined width and a predetermined length, wherein the bending stress relief hole is formed in the plate and is positioned in an area corresponding to the non-display area of the display panel.

In accordance with some embodiments, the second back plate includes at least one of polyimide (PI), polyethylene naphthalate (PEN), polyethylene terephthalate (PET), or a combination thereof.

In accordance with some embodiments, the display panel includes: a first flat portion; a second planar portion facing and vertically spaced from the first planar portion; and the bent portion extending between the first flat portion and the second flat portion so as to connect the first flat portion and the second flat portion to each other, wherein the first back plate is disposed on a back surface of the first flat portion and the second back plate is disposed a back surface of the second flat portion.

Although some example embodiments of the present disclosure have been described above with reference to the accompanying drawings, the present disclosure may not be limited to those embodiments and may be implemented in various different forms. Those of ordinary skill in the technical field to which the present disclosure belongs will be able to appreciate that the present disclosure may be implemented in other specific forms without departing from or changing the technical idea or essential features of the present disclosure. Therefore, it should be understood that the example embodiments as described above are not restrictive but illustrative in all respects.

What is claimed is:

1. A display device, comprising:
a display panel including a display area, a non-display area, and a bendable area;
a first back plate and a second back plate supporting the display panel; and
a curved cover member having a cavity having a predetermined depth defined therein,
wherein the first back plate and the second back plate are seated in the cavity,
wherein the curved cover member has a flange having a predetermined height and disposed outwardly of the cavity,
wherein a general shape of the curved cover member is a sprue shape,
wherein the display panel has a bent portion in the bendable area, and
wherein the second back plate includes a flat portion corresponding to the display area, and a bending stress relief hole is formed in the flat portion.

2. The display device of claim 1, wherein in the cavity:
an optical adhesive layer is disposed on a bottom surface of the curved cover member defining the cavity,
an optical control layer is disposed on the optical adhesive layer,
the display panel is disposed on the optical control layer,
a second adhesive layer is disposed on the display panel,
the first back plate is disposed on the second adhesive layer,
a first adhesive layer is disposed on the first back plate,
the second back plate is disposed on the first adhesive layer, and
a circuit board and a bending protection layer are disposed on the second back plate.

3. The display device of claim 1, wherein in a state in which the display panel is in a flat state before the display panel is bent, the bending stress relief hole is formed on the flat portion of the second back plate at a position corresponding to an inner edge of the flange.

4. The display device of claim 3, wherein the bending stress relief hole is formed closer to a bending direction than a circuit board direction in a plate having a predetermined width and a predetermined length.

5. The display device of claim 3, wherein the bending stress relief hole has a rectangular shape in a plan view of the display device.

6. The display device of claim 3, wherein the bending stress relief hole has a center line extending along a longitudinal direction of the second back plate,
wherein the center line is positioned at a center in a width direction of the bending stress relief hole, and
wherein the center line is vertically aligned with an inner edge of the flange of the curved cover member.

7. The display device of claim 2, wherein the bending stress relief hole does not vertically overlap with the circuit board but vertically overlaps with the bending protection layer.

8. The display device of claim 2, wherein in a state in which the optical adhesive layer, the optical control layer, the display panel, the second adhesive layer, the first back plate, the first adhesive layer, the second back plate, and the circuit board and the bending protection layer are sequentially and upwardly stacked on the bottom surface of the curved cover member defining the cavity, an upper surface of each of the circuit board and the bending protection layer as an uppermost layer is coplanar with an upper surface of the flange.

9. The display device of claim 2, wherein in a state in which the optical adhesive layer, the optical control layer, the display panel, the second adhesive layer, the first back plate, the first adhesive layer, the second back plate, and the circuit board and the bending protection layer are sequentially and upwardly stacked on the bottom surface of the curved cover member defining the cavity, a vertical level of an upper surface of the flange is lower than a vertical level of an upper surface of each of the circuit board and the bending protection layer as an uppermost layer.

10. The display device of claim 1, wherein the bending stress relief hole has a length smaller than a length of the second back plate.

11. The display device of claim 1, wherein the bending stress relief hole is formed in a plate having a predetermined width and a predetermined length of the second back plate in the non-display area of the display panel.

12. The display device of claim 1, wherein the second back plate includes at least one of polyimide (PI), polyethylene naphthalate (PEN), and polyethylene terephthalate (PET), or a combination thereof.

13. The display device of claim 1, wherein the display panel includes:
a first flat portion;
a second flat portion facing and vertically spaced from the first flat portion; and
the bent portion extending from the first flat portion and bent in a back direction in the bendable area, and disposed between the first flat portion and the second flat portion,
wherein the first back plate is disposed on a back surface of the first flat portion and the second back plate is disposed a back surface of the second flat portion.
